(19) United States
(12) Patent Application Publication
(10) Pub. No.: US 2026/0259489 A1
(43) Pub. Date: Sep. 3, 2026

(54) ORGANOMETALLIC PRECURSORS FOR NANOMATERIALS AND PELLICLE FOR EUV PHOTOLITHOGRAPHY AND MEHOD OF FORMATION

(71) Applicant: Feng Lu, Irvine, CA (US)

(72) Inventor: Feng Lu, Irvine, CA (US)

(21) Appl. No.: 19/546,373

(22) Filed: Feb. 22, 2026

Related U.S. Application Data
(60) Provisional application No. 63/764,878, filed on Feb. 28, 2025.

(51) Int. Cl. G03F 7/004; G03F 1/62; G03F 7/00

(52) U.S. Cl. CPC G03F 7/0042; G03F 1/62; G03F 7/70033

(57) ABSTRACT

Organometallic precursors to form nanomaterials and pellicles for Extreme ultraviolet (EUV) photolithography and method of formation are described. Organometallic precursors contain cyclopentadienyl or substituted cyclopentadienyl group. The method for organometallic precursors to form nanomaterials which are suitable for formation of pellicle for EUV lithography include photolysis, or photo-induced decomposition, thermolysis, or thermal-induced decomposition, wherein the nanomaterials comprise one-dimensional (1D), two dimensional (2D), or three-dimensional (3D) nanomaterials, such as nanotube, nanofiber, nanosheet, nanowire, or nanoparticles. The method for nanomaterials to form pellicle for EUV photolithography includes vacuum filtration, and/or compressing relevant nanomaterials to form transparent disc or pellet or film or membrane as pellicle under high pressure.

### CROSS REFERENCE TO RELATED APPLICATIONS

This application claims priority to U.S. provisional patent application No. 63/764,878 filed on Feb. 28, 2025 to Lu, entitled “Organometallic precursors for nanomaterials and pellicle for EUV photolithography and method of formation”, of which is entirely incorporated herein by reference.

### FIELD OF INVENTION

The present invention relates to organometallic precursors to form nanomaterials and pellicles for Extreme ultraviolet (EUV) photolithography and method of formation, wherein the organometallic precursors contain cyclopentadienyl or substituted cyclopentadienyl group. The nanomaterials comprise one-dimensional (1D), two dimensional (2D), or three-dimensional (3D) nanomaterials, such as nanotube, nanofiber, nanosheet, nanowire, or nanoparticles. The method to form nanomaterials which are suitable for formation of pellicle for EUV lithography includes photolysis, or photo-induced decomposition, thermolysis, or thermal-induced decomposition of the organometallic precursors under ambient conditions. Additionally, the method to form pellicle for EUV photolithography also includes compressing nanomaterials to form transparent disc or pellet or film or membrane under high pressure.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

However, there are potential damages to EUV photolithography patterning during the radiation process due to pollutants in the chamber of scanner. In order to protect photoresist or photo mask from potential damages during photolithography, such as dust, moisture, or other small fragments from photolithography or related processing. A pellicle is required as a protection film with high transparency, high mechanical strength and stability, high endurability, low reflectivity, low thermal expansion, and prolonged lifetime, which is usually attached to one side of photo mask for protection by glue or pressure.

### SUMMARY

The present invention pertains to organometallic precursors to form nanomaterials including one-dimensional (1D), two-dimensional (2D), or three-dimensional (3D) nanomaterials (e.g., nanotube, nanofiber, nanosheet, or nanoparticles) through photolysis, or photo-induced decomposition, thermolysis, or thermal-induced decomposition under ambient conditions, for example, under high vacuum, or high pressure, or high temperature. Then as-formed nanomaterials can be used to manufacture a pellicle film for EUV photolithography. The present invention also pertains to a method of manufacturing of a pellicle for EUV photolithography comprises attaching a plurality of nanomaterials in solid or in solution state under reduced pressure, or compressing in solid state under high pressure, in the absence of water and oxygen, to form transparent plate film with high transmittance, high mechanical strength, excellent stability and endurability.

The present invention pertains to organometallic precursors containing cyclopentadienyl or substituted cyclopentadienyl for preparation of nanomaterials depicted as below:

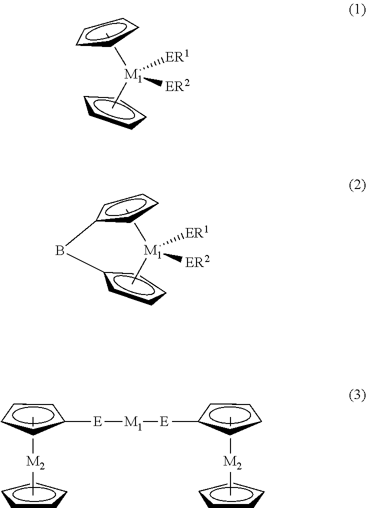

wherein M₁=Mo, W, Ti, Zr, or Hf, E=S, Se, or Te, M₂=Fe, V, Ru, Nb, Cr, Co, Nb, In, Mn, or Sn; R¹, R² are each independently H, a substituted or unsubstituted alkyl group with 1 to 20 carbon atoms, a substituted or unsubstituted alkenyl or alkynyl group with 2 to 20 carbon atoms, a substituted or unsubstituted cycloalkyl or cycloalkenyl group with 3 to 20 carbon atoms, or a substituted or unsubstituted aryl group with 6 to 20 carbon atoms, or an alcohol, amino, cyano, ether, ester, halide, nitro, silyl, thiol, or carbonyl group; wherein B is ansa-bridge comprising a substituted or unsubstituted alkyl group with 1 to 20 carbon atoms, a substituted or unsubstituted alkenyl or alkynyl group with 2 to 20 carbon atoms, or a substituted or unsubstituted cycloalkyl or cycloalkenyl group with 3 to 20 carbon atoms, or a substituted or unsaturated aryl group with 6 to 20 carbon atoms.

Wherein cyclopentadienyl (Cp) comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, a substituted or unsubstituted alkyl group with 1 to 20 carbon atoms, a substituted or unsubstituted alkenyl or alkynyl group with 2 to 20 carbon atoms, a substituted or unsubstituted cycloalkyl group with 3 to 20 carbon atoms, or a substituted or unsubstituted aryl group with 6 to 20 carbon atoms, or an alcohol, amino, cyano, ether, ester, halide, nitro, silyl, thiol, or carbonyl group.

In some embodiments, the invention pertains to organometallic precursors to form transition metal dichalcogenides (TMDs) nanomaterials including one-dimensional, two-dimensional, or three-dimensional nanomaterials under ambient conditions.

In some embodiments, the invention pertains to a methodology to synthesize organometallic precursors bearing cyclopentadienyl group. The methodology includes, but not limited to, the reaction of Cp₂M₁X₂ or BCp₂M₁X₂ with R^{1/2}EM′ (M₁=Mo, W, Ti, Zr, or Hf, M′=Li, Na, or K; X=F, Cl, Br, or I; E=S, Se, or Te), or the reaction of [(C₅H₅)M₂C₅H₄EM′] (M₂=Fe, V, Ru, Nb, Cr, Co, Nb, In, Mn, Zn, or Sn) with M₁X₂ under ambient condition. Organometallic precursors may be prepared through the lithiation of appropriate organic ligands bearing two cyclopentadienyl groups with strong bases (e.g., methyllithium, n-butyllithium, t-butyllithium, or LiBEt₃H) under ambient conditions, then followed by reaction with M₁X₄ (X=F, Cl, Br, or I) to afford Cp₂M₁X₂ or BCp₂M₁X₂, or the reaction of [(C₅H₅)M₂C₅H₄Li] with elemental chalcogen (sulfur, selenium, or tellurium) to afford [(C₅H₅)M₂C₅H₄EM′] under ambient condition.

### BRIEF DESCRIPTION OF THE DRAWINGS

FIGS. 1 and 2 show formation of nanomaterials through photolysis, or photo-induced decomposition; thermolysis, or thermal-induced decomposition of organometallic precursors bearing cyclopentadienyl group under ambient conditions, respectively.

FIG. 3 shows manufacturing of nanomaterials to be pellicle for EUV photolithography under high pressure, and/or high temperature, and press dies for manufacturing.

FIG. 4 illustrates a flowchart of organometallic photoresist radiation photolithography patterning processing over a surface of semiconductor substrate.

### DETAILED DESCRIPTION

The present invention pertains to organometallic precursors for formation one-dimensional (1D), two-dimensional (2D), or three-dimensional (3D) nanomaterials and pellicle for EUV photolithography, and a method of formation, wherein the organometallic precursors containing cyclopentadienyl can be carried out photolysis, or photo-induced decomposition, or thermolysis, or thermal-induced decomposition under ambient conditions to form nanomaterials. A method of manufacturing of nanomaterials to be pellicle for EUV photolithography includes attaching a plurality of nanomaterials in solid or in solution state under reduced pressure, or compressing solid nanomaterials under high pressure, to form transparent plate film with high transmittance, high mechanical strength and stability, and excellent endurability.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched-chain hydrocarbon of 1 to 20 carbon atoms. The terms “alkenyl, alkynyl” refers to hydrocarbon of 2 to 20 carbon atoms, “cycloalkyl, cyclokenyl” refers to hydrocarbon of 3 to 20 carbon atoms. The term “aryl” refers to unsubstituted or substituted aromatic group with 6 to 20 carbon atoms. The substituted groups include, but not limited to, amide, amine, cyano, ether, cyclic ether, ester, cyclic ester, halide, imine, nitro, silyl, thiol, or carbonyl group. The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like.

The term “amine” refers to primary (—NH₂), secondary (—NHR), tertiary (—NR₂) amine group. The term “cyclic amine” refers to [R′—NH—R″], wherein [R′—R″] is cyclic substituted and unsubstituted C₃ to C₈ organic groups.

The term “ether” refers to the R′—O—R″ group. The term “cyclic ether” refers to the [R′—O—R″], wherein [R′—R″] is cyclic substituted and unsubstituted C3 to C8 organic groups.
The term “ester” refers to the R′—(C═O)—O—R″ group. The term “cyclic ester” refers to the [R—(C═O)—O—R′], wherein [R′—R″] is cyclic substituted and unsubstituted C4 to C8 organic groups.

The term “halide” refers to the F, Cl, Br, or I. The term “nitro” refers to the —NO₂. The term “silyl” refers to the —SiR′—, —SiR′₂—, or —SiR′₃ group. The term “thiol” refers to —SH group. The term “carbonyl” refers to the —C═O group. The term “oxo” refers to —O—, or ═O.

In the above described, R′, R″ are independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms.

Cycloalkenyl group comprises substituted and unsubstituted C₄ to C₈ aliphatic unsaturated organic groups including at least one double bond, for example,

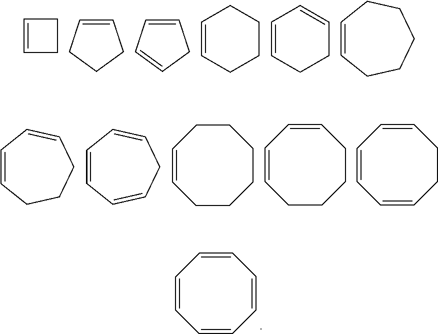

In the present disclosure, the term “substituted” refers to replacement of a hydrogen atom with a C1 to C20 alkyl group, a C2 to C20 alkene group, a C2 to C20 alkyne group, a C3 to C20 cycloalkyl group, a C6 to C20 aryl group, or other relevant functional groups such as alcohol, amino, cyano, ether, ester, halide, nitro, silyl, thiol, or carbonyl group.

The term “η¹” refers to one carbon atom bonded to one metal atom. The term “η²” refers to two carbon atoms bonded to one metal atom. The term “η³” refers to three carbon atoms bonded to one metal atom. The term “η⁴” refers to four carbon atoms bonded to one metal atom. The term “η⁵” refers to five carbon atoms bonded to one metal atom.

As described herein, the term “film”, “membrane”, “disc”, or “pellet” or similar are used to indicate “pellicle” for EUV photolithography. The term “photo mask”, “mask” are used to refer to a device to form a patterned image on a substrate plate based on a circuit pattern.

EUV lithography is under the development for the mass production of next generation <7 nm node. EUV photoresists are required to achieve higher performance, higher sensitivity and resolution, and cost reduction.

EUV light has been applied for photolithography at about 13.5 nm. In some embodiments, the EUV light can be generated from Sn plasma or Xe plasma source excited using high energy lasers or discharge pulses.

A satisfactory pellicle for EUV photolithography must have the following properties; (1) non-EUV light absorption or very low EUV light absorption; (2) excellent filtration with blocking ability for small particles, like nanoparticles (e.g., >20 nm) or dust; (3) high chemical stability and durability, particularly at high hydrogen radical operation environment, or under moisture atmosphere; (4) high thermal stability and UV light stability, or tolerance to high energy radiation like EUV or e-beam; (5) high mechanical strength for physical operations.

Pellicle can be generally divided into two types, conventional organic film, and novel inorganic film. The front includes organic polymers, such as, nitrocellulose, fluoropolymers, cellulose acetate, etc. The organic pellicle is usually available for ultraviolet (UV), vacuum ultraviolet (VUV), or deep ultraviolet (DUV), or longer wavelength radiation with very limited absorption, or no absorption. The latter contains inorganic nanomaterials, such as one-dimensional (1D), or two-dimensional (2D), or three-dimensional (3D) nanomaterials like carbon nanotubes, graphene, or graphene oxide, or fullerenes, or ceramic, or metal, or polysilicon, or silicide, etc.

In general, a pellicle film must have a high transparency with a low light absorption and reflectivity, particularly low EUV absorption. Due to strong EUV absorption of organic film such as organic polymeric film, as a result low EUV absorption inorganic film has attracted significant attention, such as polysilicon, carbon nanotube, graphene, or transition metal dichalcogenides.

However, the organic pellicle film has strong EUV light absorption at 13.5 nm, which limits their application for the advance EUV radiation. The general optical transmission losses can be ascribed to absorption, reflection, and/or scattering. The thickness of pellicle membrane also will impact on the transmission. The stability and endurability are important for the pellicle with cost-effect.

In some embodiments, a pellicle for EUV photo mask contains a membrane or a plurality of membranes.

In some embodiments, a pellicle has a structure comprising a membrane or a plurality of membranes, a frame, or a protection cover or a plurality of protection covers on the membrane. The membrane attaches on the frame. The protection cover is on the membrane.

Recently nanomaterials (NMs) including one-dimensional (1D), two-dimensional (2D), and three-dimensional (3D) NMs have been applied as manufacturing a pellicle film for EUV photolithography (e.g., for an EUV photo mask), particularly carbon nanotubes, graphene, TMDs. A combination of plurality of NMs including 1D/2D/3D has been used as film layer, such as carbon nanotubes. Considering the fact, the elements containing by the NMs must have non-EUV light absorption, or very low EUV light absorption. Therefore, the elements for the construction of NMs with required properties are limited.

The application of one-dimensional (1D), two-dimensional (2D), or three-dimensional (3D) nanomaterials for pellicle film can improve the heat dissipation or thermal tolerance and avoid the potential burnt out of pellicle by high energy EUV or likes during the photolithography radiation. High EUV transmittance, high mechanical strength, and high stability to oxygen or hydrogen are generally required.

Generally, the nanotubes can be single-wall nanotubes or multi-wall nanotubes including carbon nanotubes, or non-carbon nanotubes (e.g., TMDs nanotubes).

Particularly, carbon nanotubes include single-wall and multi-wall nanotubes with high EUV transmittance (e.g., >96.5%), which can be used as EUV photolithography mask.

In some embodiments, a plurality of single-wall carbon nanotubes and single-wall non-carbon nanotubes are applied. In other embodiments, a plurality of multi-wall carbon nanotubes and multi-wall non-carbon nanotubes are applied. In further embodiments, a plurality of single-wall and multi-wall nanotubes including carbon and non-carbon nanotubes are applied.

Besides conventional carbon nanotubes, other non-carbon inorganic nanotubes have also attracted extensive interests and attention, particularly for the development of pellicle for EUV photolithography, for example transition metal dichalcogenides (TMDs) 1D/2D/3D NMs (e.g., MoS₂, MoSe₂, WS₂, WSe₂ nanotubes).

In some embodiments, transition metal dichalcogenides (ME₂) nanomaterials, particularly nanotubes, wherein M includes molybdenum (Mo), tungsten (W), titanium (Ti), zirconium (Zr), hafnium (Hf), palladium (Pd), hafnium (Hf), or platinum (Pt); E=sulfur(S), selenium (Se), or tellurium (Te), are applied for manufacturing a pellicle film for EUV photolithography.

The general method for the preparation of transition metal dichalcogenides (TMDs) nanomaterials (e.g., nanotube) comprises two types of precursors. The conventional first type precursors for metal sources include oxides (e.g., W₃O₉, WO₃, MO₃, Mo(CO)₆, W(CO)₆), the second precursors for chalcogenide sources are usually elementals, such as sulfur(S), selenium (Se), or tellurium (Te), or relevant chalcogenide-containing compounds.

Usually, the reduction of transition metal oxide (e.g., MoO₃, WO₃) or formation of transition metal dichalcogenides (e.g., WS₂, WSe₂) by elemental chalcogen (e.g., S, Se, or Te) is only the possible in the presence of hydrogen (H₂).

Organometallic compounds have high ultraviolet light absorption because metals have high absorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Meanwhile, the light sensitive property may be beneficial for the synthesis of nanomaterials through photolysis, or photo-induced decomposition strategy.

In some embodiments, organometallic precursors containing M-C bond are light sensitive, such as to ultraviolet light (UV), deep ultraviolet light (DUV), or extreme ultraviolet light (EUV).

Therefore, in some embodiments, due to the strong UV, DUV, or EUV absorption and the dissociation of C-M bond, organometallic compounds may be used as precursors to form 1D/2D/3D nanomaterials, particularly transitional metal dichalcogenides (TMDs) NMs, through photolysis, or photo-induced decomposition, thermolysis, or thermal-induced decomposition under ambient conditions, such as at high temperature, or under high pressure, or under high vacuum or extra high vacuum.

Because cyclopentadienyl group (C₅R₅, or Cp) may impart photosensitivity to organometallic compounds. The formed Cₚ-M bond may promote suitable solubility in organic solvent to cyclopentadienyl-containing organometallic compounds. Accordingly, Cₚ-M bond containing organometallic compound, according to an embodiment, may be suitable for formation nanomaterials and/or pellicle for EUV photolithography.

The present invented organometallic precursors bearing cyclopentadienyl group for preparation of transitional metal dichalcogenides (TMDs) 1D/2D/3D nanomaterials are depicted as below,

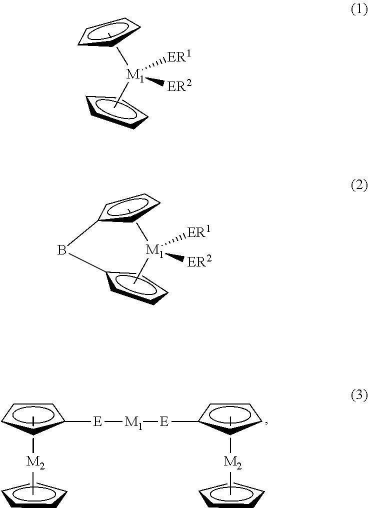

wherein M₁=Mo, W, Ti, Zr, or Hf; E=S, Se, or Te, M₂=Fe, V, Ru, Nb, Cr, Co, Nb, In, Mn, Zn, or Sn; R¹, R² are each independently H, a substituted or unsubstituted alkyl group with 1 to 20 carbon atoms, alkenyl, alkynyl group with 2 to 20 carbon atoms, cycloalkyl, or cycloalkenyl group with 3 to 20 carbon atoms, or a substituted or unsubstituted aryl group with 6 to 20 carbon atoms, or an alcohol, amino, cyano, ether, ester, halide, nitro, silyl, thiol, or carbonyl group; wherein B is ansa-bridge comprising a substituted or unsubstituted alkyl group with 1 to 20 carbon atoms, a substituted or unsubstituted alkylene, alkenyl, or alkynyl group with 2 to 20 carbon atoms, or a substituted or unsubstituted cycloalkyl, or cycloalkenyl group with 3 to 20 carbon atoms, or a substituted or unsaturated aryl group with 6 to 20 carbon atoms, or an alcohol, amino, cyano, ether, ester, halide, nitro, silyl, thiol, or carbonyl group; or containing oxygen (O), sulfur(S), selenium (Se), or tellurium (Te).

The organometallic precursors contain cyclopentadienyl C₅H₅ (Cp) group or substituted cyclopentadienyl C₅H₃R, C₅H₂R₂, C₅HR₃, C₃R₄, or C₅R₅ group with hapticity of η¹, η², η³, η⁴, or η⁵ of isomers, wherein R is H, a substituted or unsubstituted alkyl group with 1 to 20 carbon atoms, alkenyl, alkynyl group with 2 to 20 carbon atoms, cycloalkyl, or cycloalkenyl group with 3 to 20 carbon atoms, or a substituted or unsubstituted aryl group with 6 to 20 carbon atoms, or an alcohol, amino, cyano, ether, ester, halide, nitro, silyl, thiol, or carbonyl group. For example, R is H, a methyl, ethyl, isopropyl, n-butyl, t-butyl, t-amyl, s-butyl, pentyl, hexyl, neopentyl, cyclohexyl, cyclopentyl, cyclobutyl, cyclopropyl, phenyl, or benzyl group.

As one of ordinary skill in the art will recognize, the organometallic precursors listed here are merely intended as illustrated examples of organometallic precursors, and are not intended to limit the embodiments to only those organometallic compounds specifically described. Rather, any suitable organometallic compounds may be used, and all such organometallic compounds are fully intended to be included within the scope of the present embodiments.

In the present disclosure, in one exemplary embodiment, for the preparation of organometallic precursors bearing cyclopentadienyl group was performed by lithiation with strong bases, e.g., methyllithium (MeLi), n-butyllithium (n-BuLi), s-butyllithium (s-BuLi), t-butyllithium (t-BuLi), or LiBEt₃H and then followed by reaction with M₁X₄ under ambient conditions, to afford Cp₂M₁X₂, which are converted to related organometallic precursors Cp₂M₁(ER¹)(ER²) (1). A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In another one exemplary embodiment, the organometallic precursors (2) ansa-bridged [n]metallocenophane can be prepared according to the following strategy:

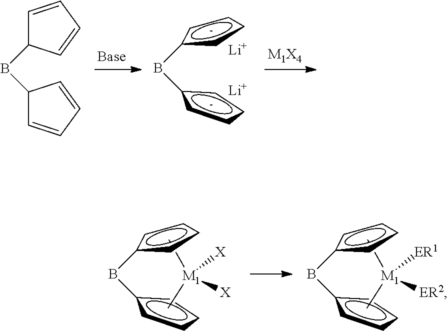

wherein B is bridge; base includes, but not limit to, methyllithium (MeLi), n-butyllithium (n-BuLi), s-butyllithium (s-BuLi), or t-butyllithium (t-BuLi), X=F, Cl, Br, or I. BCp₂M₁X₂ may be converted to ansa-bridged [n]metallocenophane (2) BCp₂M₁(ER¹)(ER²) through the reactions with appropriate reagents containing ER¹, or ER², for example, R^{1/2}SNa (e.g., ^{t}BuSNa), R^{1/2}SeNa (e.g., ^{t}BuSeNa), etc, wherein R¹, R² are independently a substituted or unsubstituted alkyl group with 1 to 20 carbon atoms, alkenyl, alkynyl group with 2 to 20 carbon atoms, cycloalkyl, or cycloalkenyl group with 3 to 20 carbon atoms, or a substituted or unsubstituted aryl group with 6 to 20 carbon atoms. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In further one exemplary embodiment, the organometallic precursors (3) may be synthesized from the reaction of (C₅H₅)M₂ (C₅H₄EM) (M=Li, Na, or K) with M₁Xₙ (n is an integral from 1 to 4) under ambient conditions, wherein E=S, Se or Te. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In some embodiments, MoS₂, MoSe₂, WS₂, WSe₂ nanotubes are formed from the reaction of bis(cyclopentadienyl) molybdenum (Cp₂Mo), or bis(cyclopentadienyl) tungsten (Cp₂W) with sulfur, or selenium at high temperature and reduced pressure, respectively.

The invention pertains to methods for preparation and purification of organometallic precursors. The methods for purification include, but not limited to, distillation, extraction, filtration, recrystallization, column chromatography, coordination, sublimation, evaporation, and a combination thereof.

In some embodiments, organometallic precursors are soluble in appropriate organic solvents for further procedure such as the preparation of nanomaterials. The solution of organometallic precursors can be formed by dissolving in organic solvents, including but not limit to, methylene chloride, chloroform, tetrahydrofuran (THF), dimethoxyethane (DME), dimethylformamide (DMF), dimethyl sulfoxide (DMSO), alcohols (e.g., 4-methyl-2-pentenol, ethanol, methanol, propanol, isopropanol, butanol), benzene, toluene, xylene, carboxylic acid, ethers (e.g., anisole), esters (e.g., ethyl acetate, ethyl lactate, butyl acetate), ketone (e.g., 2-heptanone, methyl ethyl ketone), or two or more mixtures thereof or the like.

In an embodiment, organometallic precursors are deposited on a surface of substrate for preparation of nanomaterials by wet deposition like spin-on coating, spray coating, dip coating, vapor deposition, knife edge coating. In another embodiment, organometallic precursors are deposited by chemical vapor deposition (CVD), atomic layer deposition (ALD), physical vapor deposition, or likes over the surface of substrate.

In the present invention, organometallic precursors (1), (2), (3) as sources for the formation of nanomaterials transitional metal dichalcogenides (TMDs) (e.g., MoS₂, MoSe₂, WS₂, or WSe₂) layers under ambient conditions are presented as below.

In some embodiments, the ambient conditions include photolysis, or photo-induced decomposition, thermolysis, or thermal-induced decomposition, or under high pressure, or under high vacuum or extra high vacuum, at temperature range from −196° C. to 1100° C., or under inert atmosphere.

In some embodiments, under high reduced pressure, or extra high vacuum, an organometallic precursor is deposited over the substrate, and then followed light radiation to form inorganic nanomaterials (e.g., nanotubes) at ambient temperature, such as high temperature from 20 to 1100° C.

In some embodiments, besides photolysis or photo-induced decomposition of organometallic precursors to form 1D/2D/3D nanomaterials, thermolysis, or thermal-induced decomposition of organometallic precursors may be taken place under ambient condition, for example, at high temperature (e.g., from 20 to 1100° C.), or reduced pressure (e.g., from 1×10⁻⁹ torr to 100 torr), or under high pressure, or under oxygen flow, or under inert flow/atmosphere (e.g., dinitrogen, or argon). In some embodiments, the formation of nanomaterials may take hours to days, such as from 1 hour to 6 days, which depends on the reaction conditions, or precursors features, or types of nanomaterials.

In some embodiments, chemical vapor deposition (CVD), metal-organic CVD (MOCVD), or likes are applied for the formation of nanomaterials under ambient conditions such high vacuum and high temperature, for example, the formation of nanotubes, thermolysis by CVD.

In some embodiments, the formation of 1D/2D/3D nanomaterials may be carried out on a surface of substrate (e.g., inorganic Si, SiC, SiN, SiO₂, Al₂O₃, Ga₂O₃, sapphire, ceramic, etc.).

In some embodiments, the formation of 1D/2D/3D nanomaterials may be carried out over an organic membrane (e.g., resin).

In some embodiments, the formation of 1D/2D/3D nanomaterials may be taken place at high temperature (e.g., from 200° C. to 1100° C.) surface of substrate (e.g., molten glass).

In some embodiments, the formation of 1D/2D/3D nanomaterials may be taken place at low temperature (e.g., from −196° C. to 0° C.) surface of substrate.

In some embodiments, the thickness of as-formed 1D/2D/3D nanomaterials film is from 0.1 nm to 100 nm, e.g., from 1 nm to 10 nm. The thickness determines EUV transmittance and mechanical strength of the nanomaterials-based pellicle.

In some embodiments, the thickness of as-formed 1D/2D/3D nanomaterials film may be controlled by the concentration of organometallic precursors deposited on the surface of substrate, and/or the scale of light radiation including wavelength and time scale.

In some embodiments, organometallic precursors may be sublimed for the formation of 1D/2D/3D nanomaterials.

In some embodiments, the formation of 1D/2D/3D nanomaterials from organometallic precursors may be carried out in gases gas.

In some embodiments, the formation of 1D/2D/3D nanomaterials from organometallic precursors may be carried out in liquid gas.

In some embodiments, the formation of 1D/2D/3D nanomaterials from organometallic precursors may be carried out in solid gas.

In some embodiments, the formation of 1D/2D/3D nanomaterials may be carried out over an inorganic membrane (e.g., transparent ceramic).

In some embodiments, after deposition and formation of 1D/2D/3D nanomaterials, annealing processing may be required.

In some embodiments, the surface of nanomaterials can be functionalized with various or different functional groups, including, but not limited to, —OH, —COOH, —SO₃H group, in order to improve the performance, for example, the surface functionalization of nanotubes by sulfuric acid, KMnO₄, or HNO₃.

In some embodiments, the surface of nanomaterials can be functionalized with various catalysts including, but not limited to transition metal catalysts (e.g., Pd, Pt, Ru, Mo, Ni, Ir, Rh, Co, Au, Ag, Cu, Mn, Fe, Mo, Nb, Ti, Zr, or Hf containing compounds as catalysts). Herein functionalized indicates chemical bonding or physical attaching on the surface of nanomaterials including 1D/2D/3D nanomaterials such as nanotube, nanofiber, nanowire, or nanoparticles. In some embodiments, the catalysts may be a plurality of catalysts containing different transition metals, or different catalytical compounds.

In some embodiments, nanotubes, or graphene, or graphene oxide may functionalize with inorganic nanoparticles such as metal oxide nanoparticles to improve the endurability and lifetime. The metal oxide nanoparticles include, but not limited to, TiO₂, RuO₂, MnO₂, Fe₂O₃, ZnO, ZrO₂, MoO₂, MoO₃, Al₂O₃, etc.

In some embodiments, the pellicle is constructed by a plurality of carbon nanotubes, transition metal dichalcogenides nanotubes, or boron nitride nanotubes, or a combination thereof.

In some embodiments, the plurality of nanotubes only include one type of nanotubes with identical materials, such as only carbon nanotubes.

In some embodiments, the length of nanotubes is in the range of about 0.1 μm to about 100 μm. In some embodiments, the diameter of nanotubes is in the range of about 0.1 nm to about 20 nm.

In some embodiments, the plurality of nanotubes contain two or more types of nanotubes with different materials.

In some embodiments, one-dimensional, two-dimensional, or three-dimensional nanomaterials are dispersed in a solvent. In some embodiments, the solvent includes organic solvent and water. In some embodiments, the organic solvent includes, but not limited to, hexane, pentane, diethyl ether, toluene, or benzene,

In some embodiments, the formed nanomaterials dispersed solution may be spray on the surface of substrate, then for the further manufacturing a pellicle. In one embodiments, a pellicle may be formed through vacuum filtration of nanomaterials solution.

In one embodiments, the captured nanomaterials can be plated under high pressure to form the pellicle film. In some embodiments, the solution of nanomaterials may contain a plurality of nanomaterials with different types of materials, such as a mixture of carbon nanotube and transition metal dichalcogenides. In some embodiments, after dried of one filtered nanomaterials, another solution or other solutions of nanomaterials can be filtered through to form bilayers or multi-layers.

In some embodiments, a pellicle for EUV photolithography may have multi-layers, such as two layers, or three layers, wherein every layer may have independent 1D/2D/3D nanomaterials, such as carbon nanotubes, or graphene, or transitional metal dichalcogenides (TMDs) (e.g., MoS₂, MoSe₂, WS₂, or WSe₂) nanotubes. In some embodiments, the application of multi-layers of different nanotubes may increase the mechanical strength of pellicles.

In some embodiments, the layers may have identical nanomaterials. In some embodiments, the layers may have mixed components, such as a plurality of carbon nanotubes with TMDs.

The thickness of the layers may fall in the range of about 0.1 nm to 100 nm or desired, wherein the transmittance and properties determine the thickness and the number of layers, which should meet the requirement of EUV photolithography for transparency, stability, and mechanical strength (e.g., not fragile).

In another embodiment, inorganic nanomaterials deposit on a support membrane for manufacturing the pellicle film. In some embodiments, the inorganic nanomaterials deposit on a support membrane for manufacturing the pellicle film under high external pressure, similar to the formation of KBr plate for infrared (IR) by compressed under high pressure. A person of ordinary skills in the art will recognize that the method of formation, pressure, press dies, substrate materials within the explicit ranges of above are contemplated and are within the present disclosure. In some embodiments, the support membrane is organic materials, such as porous organic polymer. In some embodiments, the support membrane is inorganic materials, such as transparent ceramic.

In some embodiments, the size of mesh or pore of the support membrane is smaller than the size of one-dimensional or two-dimensional nanomaterials, therefore the solvent of the solution of nanomaterials can be filtered through the support membrane, and the nanomaterials can be captured for the manufacturing of pellicle film. In some embodiments, the support membrane can be detached from the filtrate layer, such as nanomaterial layers.

In some embodiments, the manufacture of a pellicle may be carried out under inert atmosphere (e.g., dinitrogen, argon) without oxygen and without water, for example, in glove box.

In some embodiments, the manufacture of an inorganic pellicle film may be performed under high pressure, for example, 1×10⁹ pa.

In some embodiments, the manufacture of an inorganic pellicle film for EUV photolithography may be performed under high pressure at room temperature. In some embodiments, the manufacture of inorganic pellicle film for EUV photolithography may be performed under high pressure at high temperature, e.g., in a range from 200° C. to 1100° C. In some embodiments, nanotubes may form nanotube bundles through Joule heating.

In some embodiments, the inorganic pellicle film is made of inorganic materials, such as inorganic silicon, inorganic salts, inorganic boron nitride, silicon carbide, silicon nitride.

In some embodiments, inorganic salt (dehydrate) may be used as the materials for constructing inorganic pellicle under high external pressure, such as potassium bromide (KBr), potassium chloride (KBr), lithium chloride (LiCl), lithium bromide (LiBr), beryllium chloride (BeCl), beryllium bromide (BeBr), zinc chloride (ZnCl₂), zinc bromide (ZnBr₂), molybdenum sulfur (MoS₂), molybdenum selenium (MoSe₂), molybdenum tellurium (MoTe₂), tungsten sulfur (WS₂), tungsten selenium (WSe₂), tungsten tellurium (WTe₂), but not limited to.

In some embodiments, inorganic salts are deposited on the surface of substrate by chemical vapor deposition, physical vapor deposition, or atomic layer deposition.

In some embodiments, inorganic salts are heated to be melt or to be liquid at high temperature (for example in a range from about 200° C. to 2000° C.), and pressed under high pressure to form transparent disc or pellet or film.

In some embodiments, inorganic salts are dehydrated, such as powders or crystals.

In some embodiments, inorganic salts are in one-dimensional (1D), two-dimensional (2D), and three-dimensional (3D) nanomaterials form, e.g., nanotube, nanowire, or nanoparticles.

In some embodiments, inorganic salts are three-dimensional (3D) nanosized particles or nanoparticles, such as from 0.1 nm to 1000 nm in size.

In some embodiments, a direct deposition of nanomaterials through chemical vapor deposition (CVD), physical vapor deposition (PVD), or atomic layer deposition (ALD) over substrate is carried out.

In some embodiments, the substrate is made of, includes, but not limited to, metal (e.g., steel, iron, copper), silicon, silicon oxide (SiO₂), ceramic, silicon carbide (SiC), silicon nitride (SiN), boron nitride (BN), diamond, aluminum oxide (Al₂O₃), aluminum nitride (AlN), gallium oxide (Ga₂O₃), zirconium oxide (ZrO₂), hafnium oxide, titanium nitride (TiN), etc. The hardness of substrate is strong enough as support for the formation of transparent film or disc under high pressure without decomposition or defect.

In some embodiments, the formation of nanomaterials may be carried out within short time at relatively high speed, for example, from minutes to hours. In some embodiments, the formation of nanomaterials may be carried out within long time at relatively slow speed, for example, days. The reaction conditions, such as temperature, pressure, concentration, and organometallic precursor properties determine the generation speed of nanomaterials.

In some embodiments, an EUV pellicle mounts or glues on one side of EUV reflective mask.

In some embodiments, the layers may be attached each other by glue or adhesive such as acrylic, or silicane. In some embodiments, the layers may be attached each other under vacuum. In some embodiments, the layers may be attached each other by external high pressure.

In some embodiments, a frame is required to support the pellicle film.

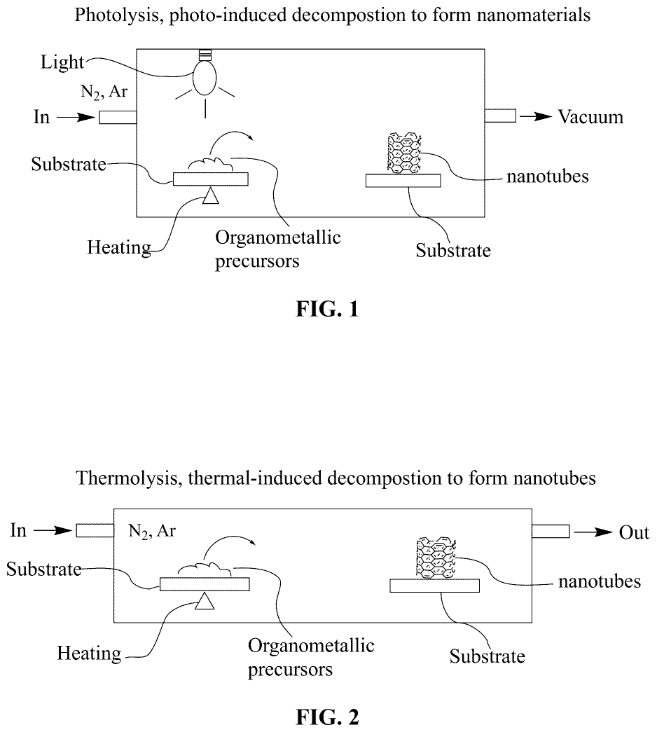

FIG. 1 depicts the formation of nanomaterials through photolysis, or photo-induced decomposition of organometallic precursors. The photo or light includes wavelengths from 0.001 nm to 4000 nm, such as visible light, infrared (IR), g-line (436 nm), i-line (365 nm) ultraviolet (UV), deep ultraviolet (DUV), extreme ultraviolet (EUV), e-beam, X-ray, or the likes. In some embodiments, the photo or light source includes, but not limited to, mercury vapor lamp, xenon lam, carbon arc lamp, F2 excimer laser light (wavelength 157 nm), ArF excimer laser light (193 nm), KrF excimer laser light (248 nm), CO₂ laser (13.5 nm), or neodymium-doped yttrium aluminum garnet (Nd: YAG) laser. In some embodiments, the formation processing may be carried out under vacuum with organometallic precursor vapor inside a reactor or chamber, such as gas phase reaction. In some embodiments, the reactant organometallic precursors may be injected into the reaction chamber or reactor as reaction gas for photolysis, or photo-induced decomposition to form nanomaterials. In some embodiments, the organometallic precursors may be vaporized in a reactor or chamber accompanying with photolysis or decomposition, formation and deposition of nanomaterials on the substrate. Nanomaterials include 1D, 2D, or 3D nanomaterials, including, but not limited to, nanotubes, nanowires, nanosheets, nanofibers, or nanoparticles. In some embodiments, the organometallic precursors may be vaporized at high temperature, such as in the range of 20° C. to 1100° C.

FIG. 2 depicts the formation of nanomaterials through thermolysis, or thermal-induced decomposition. In some embodiments, the organometallic precursors may be vaporized in the reactor accompanying with thermolysis, or thermal-induced decomposition under vacuum. In some embodiments, the organometallic precursors may be vaporized or sublimized in the reactor accompanying with thermolysis, or thermal-induced decomposition under inert atmosphere, such as nitrogen, argon, helium, krypton, or xenon gas. In an exemplary embodiment, in FIG. 2, nitrogen or argon is used as the inert atmosphere. Nanomaterials contain 1D, 2D, or 3D nanomaterials, including, but not limited to, nanotubes, nanowires, nanosheets, nanofibers, or nanoparticles. In some embodiments, the organometallic precursors may be vaporized or sublimized at high temperature, such as in the range of 20° C. to 1100° C.

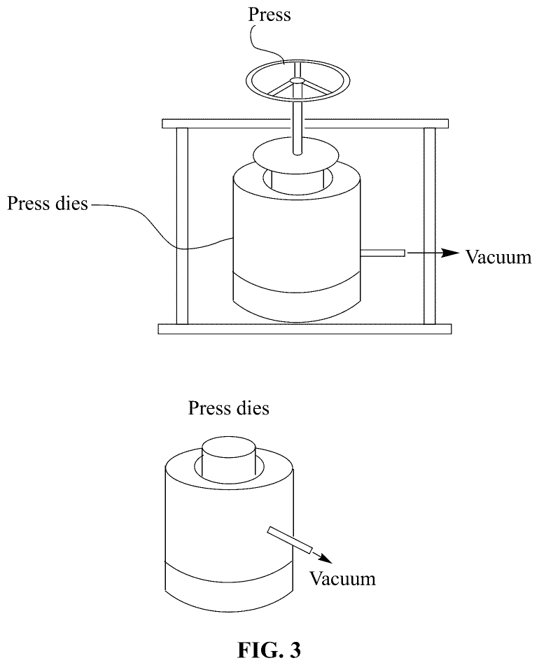

FIG. 3 illustrates the apparatus for pressing nanomaterials to form pellet or pellicle under external pressure, including press dies, presses, or the relatives. In some embodiments, the power for compressing nanomaterials is from hydraulic presses. In an exemplary embodiment, the pressure is in the range of from 1 ton to 100 ton.

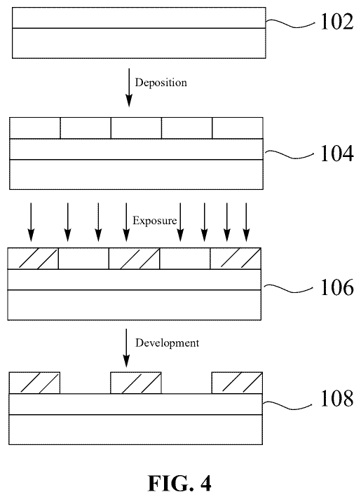

In the present disclosure, a method of forming photolithography pattern using the organometallic photoresist composition is illustrated by FIG. 4. The general photolithography process described by FIG. 4, is to deposit photoresist over a substrate 102 to form a thin photoresist layer 104; after pre-exposure baking, the formed layer is exposed to actinic radiation to form a latent image 106; after post-exposure baking, the latent is developed by the appropriate developer, such as aqueous basic/acid solutions or organic solvents, to produce the developed resist photolithography pattern 108.

Hereinafter, the present invention is described in more details through Examples regarding the preparation of organometallic precursors and conversion to nanomaterials and pellicle for EUV photolithography. However, the present invention is not limited by the Examples. A person of ordinary skills in the art will recognize that the samples and solution composition components within the explicit ranges of above are contemplated and within the present disclosure.

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the spirit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organometallic precursor for forming nanomaterials and pellicle for EUV photolithography, comprising one or more chemical molecules bearing cyclopentadienyl group selected from the following: 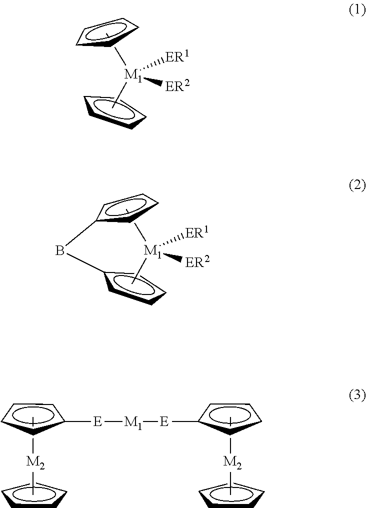
wherein M₁=Mo, W, Ti, Zr, or Hf; E=S, Se, or Te, M₂=Fe, V, Ru, Nb, Cr, Co, Nb, In, Mn, Zn, or Sn; R¹, R² are each independently H, a substituted or unsubstituted alkyl group with 1 to 20 carbon atoms, a substituted or unsubstituted alkenyl or alkynyl group with 2 to 20 carbon atoms, a substituted or unsubstituted cycloalkyl or cycloalkenyl group with 3 to 20 carbon atoms, or a substituted or unsubstituted aryl group with 6 to 20 carbon atoms, or an alcohol, amino, cyano, ether, ester, halide, nitro, silyl, thiol, or carbonyl group; wherein B is ansa-bridge comprising a substituted or unsubstituted alkyl group with 1 to 20 carbon atoms, a substituted or unsubstituted alkenyl, or alkynyl group with 2 to 20 carbon atoms, or a substituted or unsubstituted cycloalkyl, cycloalkenyl group with 3 to 20 carbon atoms, or a substituted or unsaturated aryl group with 6 to 20 carbon atoms, or an alcohol, amino, cyano, ether, ester, halide, nitro, silyl, thiol, or carbonyl group.

2. The organometallic precursor of claim 1, wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, a substituted or unsubstituted alkyl group with 1 to 20 carbon atoms, a substituted or unsubstituted alkenyl or alkynyl group with 2 to 20 carbon atoms, or a substituted or unsubstituted cycloalkyl group with 3 to 20 carbon atoms, or a substituted or unsubstituted aryl group with 6 to 20 carbon atoms, or an alcohol, amino, cyano, ether, ester, halide, nitro, silyl, thiol, or carbonyl group.

3. The organometallic precursor of claim 1, wherein the nanomaterials and pellicle are formed by photolysis, photo-induced decomposition, thermolysis, or thermal-induced decomposition of the organometallic precursors.

4. The organometallic precursor of claim 1, wherein M₁=Mo, or W; E=S, or Se.

5. The organometallic precursor of claim 1, wherein R¹, R² are a substituted or unsubstituted alkyl with 1 to 20 carbon atoms, a substituted or unsubstituted alkenyl or alkynyl with 2 to 20 carbon atoms, or a substituted or unsubstituted aryl group with 6 to 20 carbon atoms.

6. A method for formation nanomaterials and pellicle for EUV photolithography, comprising deposition of organometallic precursor over a substrate;
photolysis, photo-induced decomposition, thermolysis, or thermal-induced decomposition of the organometallic precursor to form nanomaterials;
manufacturing the nanomaterials to form pellicle.

7. The method of claim 6, wherein the organometallic precursor containing cyclopentadienyl is one or more selected from the following: 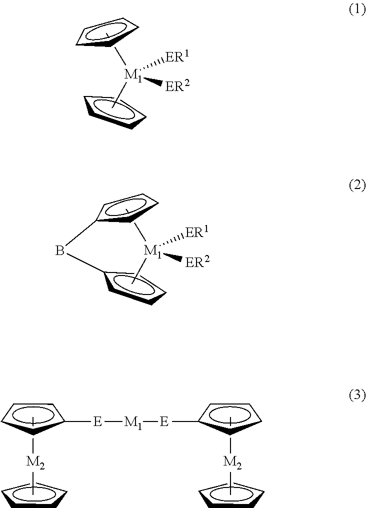
wherein M₁=Mo, W, Ti, Zr, or Hf; E=S, Se, or Te, M₂=Fe, V, Ru, Nb, Cr, Co, Nb, In, Mn, Zn, or Sn; R¹, R² are each independently H, a substituted or unsubstituted alkyl group with 1 to 20 carbon atoms, alkenyl, or alkynyl group with 2 to 20 carbon atoms, cycloalkyl, or cycloalkenyl group with 3 to 20 carbon atoms, or a substituted or unsubstituted aryl group with 6 to 20 carbon atoms, or an alcohol, amino, cyano, ether, ester, halide, nitro, silyl, thiol, or carbonyl group; wherein B is ansa-bridge comprising a substituted or unsubstituted alkyl group with 1 to 20 carbon atoms, alkenyl, or alkynyl group with 2 to 20 carbon atoms, or a substituted or unsubstituted cycloalkyl, or cycloalkenyl group with 3 to 20 carbon atoms, or a substituted or unsaturated aryl group with 6 to 20 carbon atoms.

8. The method of claim 7, wherein cyclopentadienyl comprises C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl group with 1 to 20 carbon atoms, alkenyl, alkynyl group with 2 to 20 carbon atoms, or cycloalkyl group with 3 to 20 carbon atoms, or a substituted or unsubstituted aryl group with 6 to 20 carbon atoms, or an alcohol, amino, cyano, ether, ester, halide, nitro, silyl, thiol, or carbonyl group.

9. The method of claim 6, wherein the photolysis, photo-induced decomposition comprises light radiation with wavelength from 0.001 nm to 4000 nm including visible light, infrared, ultraviolet light, deep ultraviolet, extreme ultraviolet, X-ray, e-beam, or the likes.

10. The method of claim 6, wherein the photolysis, photo-induced decomposition may be carried out in wet solution, or as dry method over a surface of substrate.

11. The method of claim 6, wherein the photolysis, photo-induced decomposition, thermolysis, or thermal-induced decomposition of organometallic precursor may be carried out at temperature in a range from −196° C. to 1100° C.

12. The method of claim 6, wherein the photolysis, photo-induced decomposition, thermolysis, or thermal-induced decomposition of organometallic precursor may be carried out under reduced pressure range from 1.0×10⁻⁹ torr to 100 torr.

13. The method of claim 6, wherein the nanomaterials include nanotube, nanofilm, nanoflake, nanosheet, nanowire, or nanoparticles.

14. The method of claim 6, wherein the nanomaterials comprise transition metal dichalcogenides M₁E₂ 2D nanotube, or nanowire, wherein M₁=Mo, or W; E=S, Se, or Te.

15. The method of claim 6, wherein the thermolysis, or thermal-induced decomposition may be carried out by chemical vapor deposition, metal-organic chemical vapor deposition, atomic layer deposition, or physical vapor deposition.

16. A method of manufacturing of a pellicle for EUV photolithography, comprising:
compressing nanomaterials under high pressure in the absence of water and oxygen to form transparent disc or pellet.

17. The method of claim 16, wherein the high pressure is from 1×10⁶ to 1×10¹² pa.

18. The method of claim 16, wherein the nanomaterials comprise one-dimensional, two-dimensional, or three-dimensional inorganic nanomaterials.

19. The method of claim 16, wherein the nanomaterials comprise carbon nanotube, graphene, graphene oxide, transition metal dichalcogenides nanotube/nanowire, boron nitride nanotube, silicon nanomaterials, or silicon dioxide nanomaterials.

20. The method of claim 16, wherein the pellicle comprising:
a plurality of nanomaterials made of inorganic materials to form a transparent pellicle film with thickness of 0.1 nm to 100 μm.
